(19) United States
(12) Patent Application Publication
(10) Pub. No.: US 2010/0294742 A1
(43) Pub. Date: Nov. 25, 2010

(54) Modifications to Surface Topography of Proximity Head

(76) Inventors: Enrico Magni, Pleasanton, CA (US); Robert J. O'Donnell, Fremont, CA (US); Jeffrey J. Farber, Delmar, NY (US)

Correspondence Address: MARTINE PENILLA & GENCARELLA, LLP, 710 LAKEWAY DRIVE, SUITE 200, SUNNYVALE, CA, 94085, US

(21) Appl. No.: 12/471,169

(22) Filed: May 22, 2009

(51) Int. Cl. B44C 1/22; H01L 21/306

(52) U.S. Cl. 216/53; 156/345.23; 216/83

(57) ABSTRACT

In an example embodiment, a wet system includes a proximity head and a holder for substrate (e.g., a semiconductor wafer). The proximity head is configured to cause a flow of an aqueous fluid in a meniscus across a surface of the proximity head. The surface of the proximity head interfaces with a surface of a substrate through the flow. The surface of the head is composed of a non-reactive material (e.g., thermoplastic) with modifications as to surface topography that confine, maintain, and/or facilitate the flow. The modifications as to surface topography might be inscribed on the surface with a conical scribe (e.g., with a diamond or SiC tip) or melt printed on the surface using a template. These modifications might produce hemi-wicking or superhydrophobicity. The holder exposes the surface of the substrate to the flow.

### BACKGROUND

In some new systems for processing a semiconductor wafer, a thermoplastic proximity head creates a meniscus by causing an aqueous fluid to flow across a surface of the head through the use of perforations that deposit the fluid and suction it up. In turn, this meniscus interfaces with a surface of the semiconductor wafer in order to perform such operations as etching, cleaning, rinsing, etc., the wafer's surface. See e.g., co-owned U.S. Pat. No. 7,329,321, entitled “Enhanced Wafer Cleaning Method”.

In such systems, maintenance, confinement, and facilitation of the flow of the meniscus depends inter alia on: (1) on the nature and composition of the aqueous fluid that the system is depositing, which can vary widely depending upon the function being performed by the fluid, e.g., etching, cleaning, or rinsing; and (2) parameters such as the flow rate of deposition and the flow rate of suction.

A need exists for an efficient (e.g., relatively inexpensive and reliable) and effective way to confine, maintain, and/or facilitate (e.g., by promoting spreading or reducing friction) a flow of a meniscus in a desired location or position over a surface of a semiconductor wafer (which might be moving relative to the proximity head), for use in such systems. Though the inventions claimed below provide such a means, the inventions have wide applicability outside this particular context.

### SUMMARY

In an example embodiment, a wet system includes a proximity head and a holder for a substrate (e.g., a semiconductor wafer). The proximity head is configured to cause a meniscus (e.g., of an aqueous fluid) to flow across a surface of the head. The surface of the head interfaces with a surface of a substrate through the meniscus. The surface of the head is composed of a non-reactive material (e.g., thermoplastic) with modifications as to surface topography that confine, maintain, and/or facilitate (e.g., by promoting spreading or reducing friction) the flow of the meniscus. The modifications as to surface topography might be directly inscribed or melt printed using a template. These modifications might induce hemi-wicking properties in the surface. Alternatively, with the appropriate topography, superhydrophobic behavior can be achieved.

In another example embodiment, an automated method for a wet system includes two operations. In the method's first operation, the wet system causes a meniscus (e.g., of an aqueous fluid) to flow across a surface of a proximity head. The surface of the proximity head is composed of a non-reactive material (e.g., thermoplastic) with modifications as to surface topography that confine, maintain, and/or facilitate (e.g., by promoting spreading or reducing friction) the flow of the meniscus. The modifications as to surface topography might be directly inscribed or melt printed using a template. These modifications might produce hemi-wicking or superhydrophobicity. In the method's second operation, the wet system exposes a surface of a substrate (e.g., a semiconductor wafer) to the flow of the meniscus.

In another example embodiment, an automated or partially automated method for manufacturing a proximity head includes two operations. The method's first operation involves forming a proximity head from (a) a component that includes a bore for delivering an aqueous fluid and a bore for a partial vacuum and (b) a component that includes a non-reactive surface (e.g., thermoplastic) having delivery perforations connected to the bore for delivering the aqueous fluid and suction perforations connected to the bore for the partial vacuum. The method's second operation involves roughening the non-reactive surface to create modifications as to surface topography that confine/maintain, and/or facilitate (e.g., by promoting spreading or reducing friction) a flow of a meniscus (e.g., of an aqueous fluid) between the delivery perforations and the suction perforations.

The advantages of the present inventions will become apparent from the following detailed description, which taken in conjunction with the accompanying drawings, illustrates by way of example the inventions' principles.

### BRIEF DESCRIPTION OF THE DRAWINGS

FIG. 1a is a simplified schematic diagram illustrating a contact angle between a liquid and a solid surface.

FIG. 1b includes two simplified schematic diagrams illustrating hemi-wicking.

FIG. 1c is a simplified schematic diagram illustrating superhydrophobicity.

FIG. 2 is a simplified schematic diagram of a pair of proximity heads in a linear wet system, in accordance with an example embodiment.

FIG. 3 is a simplified schematic diagram of various interfacing surfaces for a proximity head, in accordance with example embodiments.

FIGS. 4a and 4b are composite diagrams showing a comparison of a thermoplastic solid with and without inscription of the solid's surface, in accordance with an example embodiment.

FIGS. 5a-1, 5a-2, 5a-3, and 5a-4 and FIGS. 5b-1, 5b-2, 5b-3, and 5b-4 are composite diagrams showing a comparison of the surface texture parameters for a thermoplastic solid with and without inscription of the solid's surface, in accordance with an example embodiment.

FIG. 6 is a flowchart diagram of a process for exposing a surface of a substrate (e.g., a semiconductor wafer) to a flow of a meniscus, in accordance with an example embodiment.

FIG. 7 is a flowchart diagram of a process for producing modifications to the topography of an interfacing surface of a proximity head, in accordance with an example embodiment.

### DETAILED DESCRIPTION

In the following description, numerous specific details are set forth in order to provide a thorough understanding of the example embodiments. However, it will be apparent to one skilled in the art that the example embodiments may be practiced without some of these specific details. In other instances, implementation details and process operations have not been described in detail, if already well known.

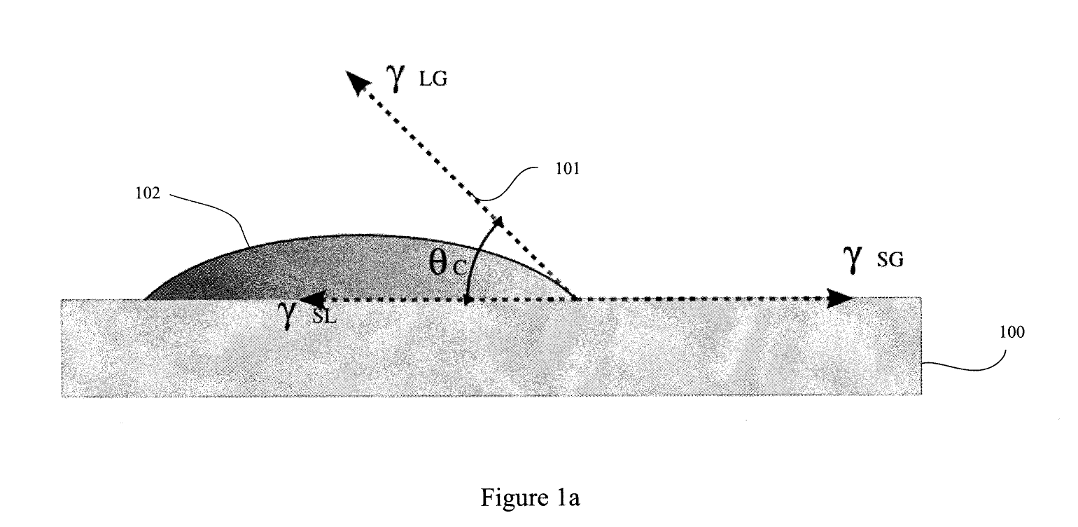

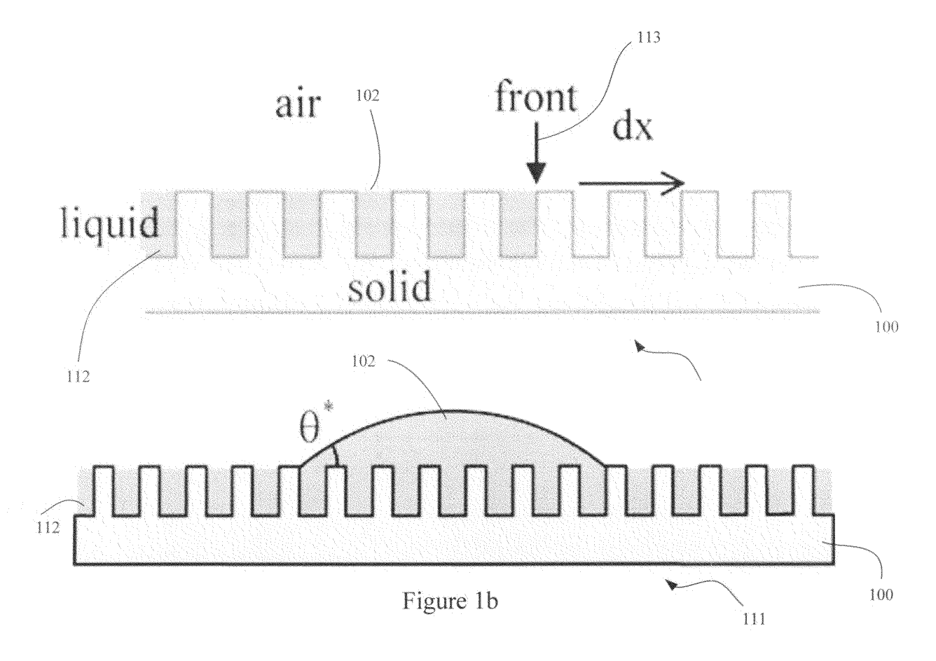

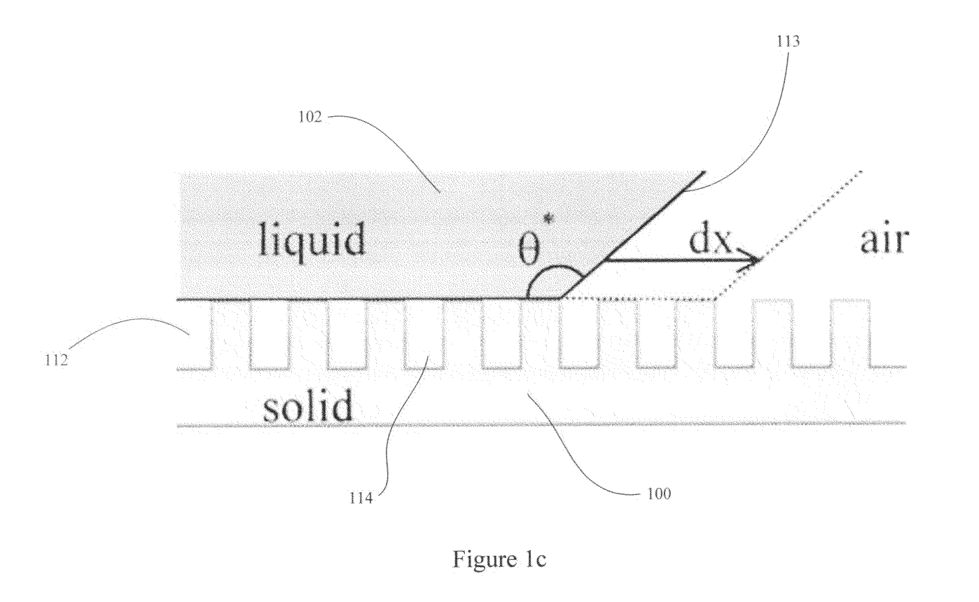

FIG. 1a is a simplified schematic diagram illustrating a contact angle between a liquid drop and a solid surface. As shown in this figure, a contact angle θ_{C} is the angle formed between a solid surface 100 and a line 101 that (a) is tangent to a liquid drop 102 and (b) whose origin is at the intersection of the drop 102 and a solid surface 100. The other items labeled in this figure show the interfacial or surface energies related to the three different phases (Gas, Liquid, and Solid) which are parameters in the Young Equation, as will be appreciated by one of ordinary skill in the art. This figure makes no assumption about the nature of the liquid, e.g., whether it is aqueous. It will be appreciated that if the drop's liquid is strongly attracted to the solid surface 100, the drop 102 will completely spread out on the solid surface 100 and the contact angle θ_{C} will be close to 0 degrees.

If the liquid is aqueous, such a surface might be referred to as super-hydrophilic. Less strongly hydrophilic solids typically exhibit contact angles up to 90 degrees. Conversely, if the solid surface is hydrophobic, the contact angle tends to be larger than 90 degrees. On strongly hydrophobic surfaces, the contact angles might reach 150 degrees or even nearly 180 degrees. On such surfaces, the water droplets simply rest on the surface, without actually wetting the surface to any significant extent. These surfaces might be referred to as superhydrophobic and have been obtained on micro-patterned fluorinated surfaces (e.g., surfaces with a Teflon-like coating), for example.

FIG. 1b includes two simplified schematic diagrams illustrating hemi-wicking. The diagrams and the term “hemi-wicking” come from a publication: Jose Bico, Uwe Thiele, and David Quere, Wetting of Textured Surfaces, Colloids and Surfaces A: Physicochemical and Engineering Aspects, Vol. 206, No. 1 (July 2002), pp. 41-46. It will be recalled that wicking is another term for capillary action and alludes to the mechanical property of candle wicks. As shown in the top diagram 110, hemi-wicking might occur when a solid surface 100 includes microchannels 112 which soak up a water drop 102, much as a sponge might do, making the solid surface 100 hydrophilic or super-hydrophilic. Indeed, at a high level of abstraction, one might think of hemi-wicking as involving a two-dimensional sponge. The top diagram 110 describes the case where the water drop 102 is not large enough to fill all the microchannels 112. So the drop has a front 113 which is moving to the right, as indicated by the arrow labeled dx. The bottom diagram 111 describes the case where the water drop 102 is sufficient to fill the microchannels 112. In this case, the water drop 102 has an apparent contact angle θ*, which is less than 90 degrees, as would one expect for a hydrophilic surface.

FIG. 1c is a simplified schematic diagram illustrating superhydrophobicity. This diagram also comes from the publication, Wetting of Textured Surfaces. As depicted in this diagram, a water drop 102 sits atop the microchannels 112 of a solid surface 100. In between the microchannels 112 are pockets of air 114, which help to make the solid surface 100 hydrophobic or superhydrophobic. The water drop 102 has a front 113 that is moving to the right, as indicated by the arrow labeled dx. The water drop 102 has an apparent contact angle θ*, which is greater than 90 degrees, as would one expect for a hydrophobic or superhydrophobic surface. Recent research has suggested that superhydrophobicity might be used to promote the low friction flows of aqueous fluids. See e.g., Cecile Cottin-Bizonne, Jean-Louis Barrat, Lyderic Bocquet, and Elisabeth Charlaix, Low-friction Flows of Liquid at Nonpatterned Interfaces, Nature Materials, Vol. 2 (April 2003), pp. 237-240.

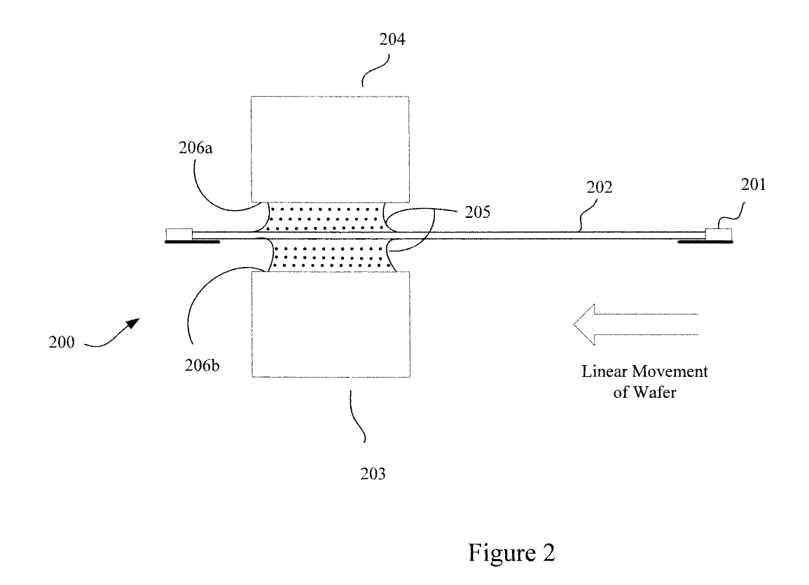

FIG. 2 is a simplified schematic diagram of a pair of proximity heads in a linear wet system, in accordance with an example embodiment. In this figure, a linear wet system 200 includes a top proximity head 204 with an interfacing surface 206a and a bottom proximity head 203 with an interfacing surface 206b. Each of these proximity heads forms a fluid meniscus 205 through which a semiconductor wafer 202 is linearly transported by a carrier 201 with pins on which the semiconductor wafer rests, exposing its surfaces. The meniscus region might cover small or large portions of the surface of semiconductor wafer 202. In this regard, see co-owned U.S. Patent Published Application No. 2008/0081775, entitled “Carrier for Reducing Entrance and/or Exit Marks Left by a Substrate-Processing Meniscus”, filed on Sep. 29, 2006, which is incorporated herein by reference.

In an example embodiment, the meniscus might be wider than the wafer diameter in a first direction (e.g., the direction of the long axis of a proximity head) and approximately 2 cm wide in a second direction that is normal to the first direction (e.g., the direction of wafer movement). In an example embodiment, the fluid might be an aqueous solution such as deionized water (DIW). It will be appreciated that when the semiconductor wafer 202 and the carrier 201 enter and exit the fluid meniscus 205, the meniscus faces forces that might deflect it, attract it, or otherwise cause the meniscus's confinement to break down. Similar forces might cause the meniscus's confinement to break down even when the semiconductor wafer 202 is in the interior of the meniscus 205 or when no wafer is present.

In an alternative example embodiment, the linear wet system 200 might have only a top proximity head 204 or only a bottom proximity head 203, rather than a pair of proximity heads. Also, in an alternative example embodiment, the wet system might be a rotational or spinning wet system rather than a linear wet system.

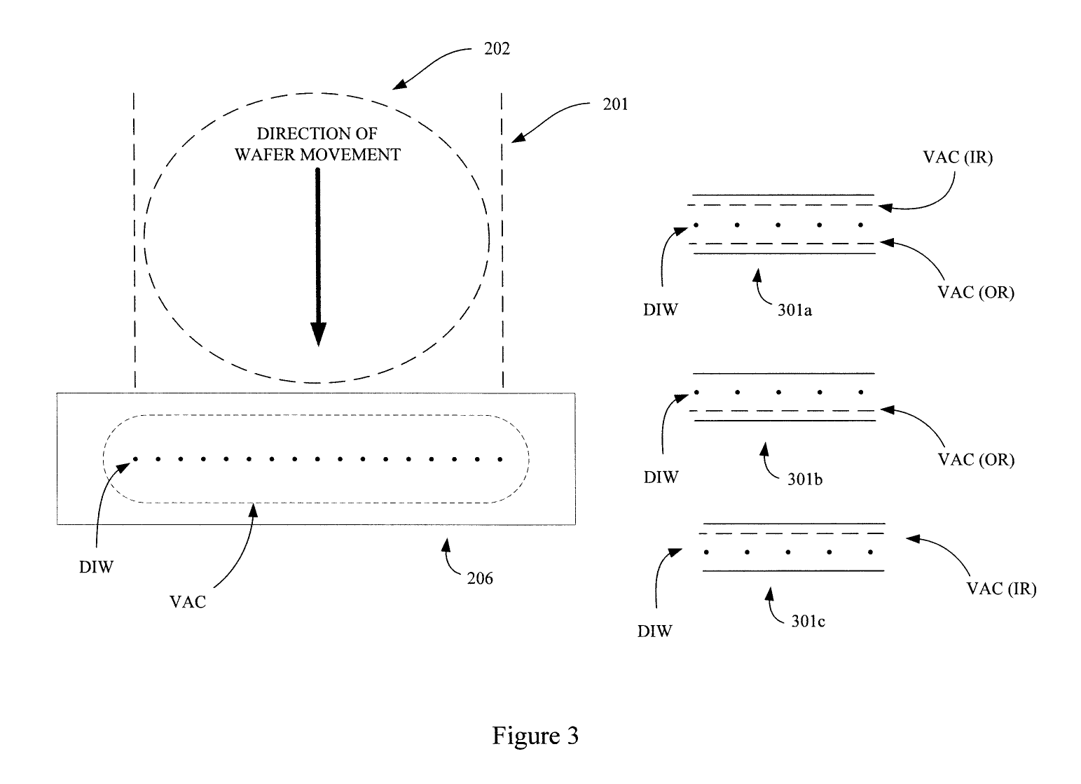

FIG. 3 is a simplified schematic diagram of various interfacing surfaces for a proximity head, in accordance with an example embodiment. As used in this specification, an interfacing surface of a proximity head is the surface of the head that interfaces (e.g., through the medium of an aqueous fluid) with a substrate (such as semiconductor wafer 202 on carrier 201), which substrate is located above, below, or to the side of the interfacing surface. In an example embodiment, an interfacing surface might be made of a non-reactive thermoplastic such as polyvinylidene chloride (PVDF) or KYNAR (also called HYLAR or SYGEF). In other alternative example embodiments, the interfacing surface might be made of a non-reactive thermoplastic such as ethylene chlorotrifluoroethlyene (ECTFE) or halar. It will also be appreciated that without modifications as to surface topography, a non-reactive thermoplastic such as KYNAR tends to be hydrophobic, but not superhydrophobic.

It will be appreciated that it is advantageous for the interfacing surface to be non-reactive since the aqueous fluid deposited by the interfacing surface itself might be reactive or the deposited aqueous fluid might be etching, cleaning, or rinsing a fluid or solid that is reactive. However, in alternative example embodiments, the interfacing surface might be made of a non-reactive thermoset plastic or a non-reactive ceramic. That is to say, one might substitute any suitable (e.g., non-reactive and inscribable, micro-machinable, roughable, settable, shapeable, etc.) material for thermoplastic as the material for the interfacing surface.

As shown in FIG. 3, an interfacing surface 206 (e.g., 206a or 206b from FIG. 2) of a proximity head might include two sets of perforations. An interior set of perforations might deposit an aqueous fluid (e.g., DIW) which is then suctioned up by an exterior set of perforations (e.g., VAC), creating a flow of a meniscus between the interior set of perforations and the exterior set of perforations. This arrangement of the perforations is consistent with the extract shown in 301a. Extracts 301b and 301c show alternative arrangements for the perforations on an interfacing surface. In extract 301b, there is no top exterior set of perforations for suctioning an aqueous fluid. In extract 301c, there is no bottom exterior set of perforations for suctioning an aqueous fluid. It will be appreciated that each of these latter two alternative arrangements supports a flow of a meniscus, albeit in only one direction with respect to wafer movement.

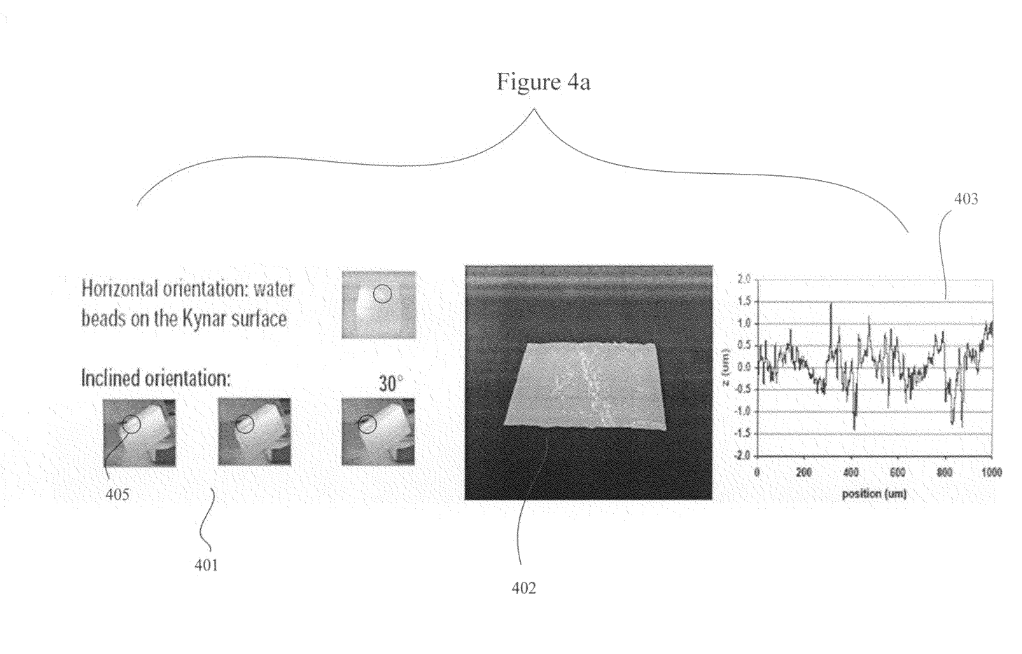

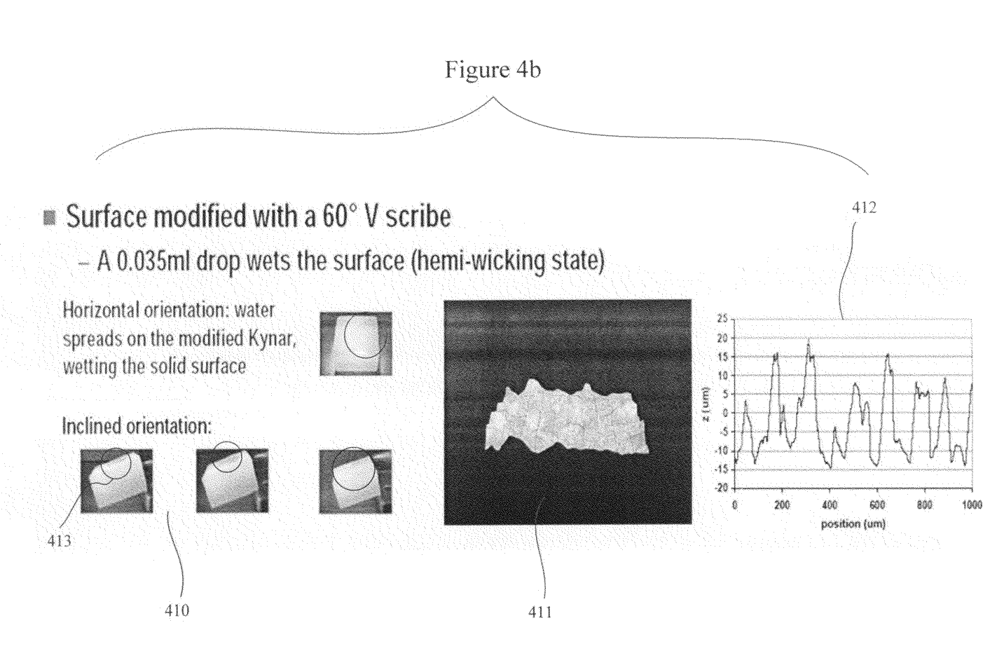

FIGS. 4a and 4b are composite diagrams showing a comparison of a thermoplastic solid with and without inscription of the solid's surface, in accordance with an example embodiment. FIG. 4a shows the case of a thermoplastic solid without inscription of the solid's surface. As indicated in the figure, the thermoplastic solid might be KYNAR (e.g., KYNAR 740), in an example embodiment. Such a solid has a low surface (or interfacial) energy with respect to the liquid and solid phases that are present when a drop of water is placed on a surface of the solid. That is to say, the solid's surface is hydrophobic. This hydrophobicity is shown in the photographs 401 of a drop 405 (e.g., 0.035 ml) of water on the solid's surface. When the solid's surface is not inclined, the water drop 405 rests on the surface; it does not wet the surface by spreading over it. When the solid's surface is inclined 30 degrees, the water drop 405 slides down the surface but does not exhibit spreading. The three-dimensional surface 402 results from application of a non-contact profilometer to the solid's surface. The two-dimensional plot 403 results from application of a contact profilometer to the solid's surface. The three-dimensional surface 402 is relatively flat in accord with the two-dimensional plot 403, which shows the normalized height of the surface varying within a relatively small range, e.g., between approximately plus 1.5 microns and minus 1.5 microns.

FIG. 4b shows the case of a thermoplastic solid with inscription of the solid's surface to produce hemi-wicking. As indicated in the figure, the inscription might result from inscribing small (or micro) channels in the surface, as explained in further detail below. Because of the inscription, the solid's surface is hydrophilic. This hydrophilicity is shown in the photographs 410 of a drop of water 413 (e.g., 0.035 ml) on the solid's surface. Whether or not the solid's surface is inclined, the water drop 413 spreads over the surface. The three-dimensional surface 411 results from application of a non-contact profilometer to the solid's surface. The two-dimensional plot 412 results from application of a contact profilometer to the solid's surface. The three-dimensional surface 411 includes numerous peaks and valleys, in accord with the two-dimensional plot 403, which shows the normalized height of the surface varying within a relatively large range, e.g., between approximately plus 20 microns and approximately minus 15 microns (e.g., the inscribed channels are in the range of approximately 30-35 microns deep).

Hemi-wicking of a thermoplastic surface might be obtained in a variety of ways, as discussed further below. For example, a desired pattern (e.g., of peaks and valleys or pillars and troughs) might be obtained by direct inscription (e.g., macro-machining) of the surface or by melt-printing a desired pattern onto the surface using a template or master (e.g., made of an inert metal or ceramic) previously machined with the negative of the desired pattern. In an alternative example embodiment, the thermoplastic surface might be roughened using an abrasive material such as Scotch-Brite™, though any suitable abrasive material could be substituted.

In the example embodiment shown in FIGS. 4a and 4b, the small (or micro) channels in the surface of the KNYNAR might be created by a scribe, for example, a conical scribe whose cone is 60 degrees and whose tip is made of diamond or silicon carbide or SiC (e.g., a “fiber optic” scribe), although another similar scribe (e.g., a wedge scribe) might also be suitable for this purpose. In the example embodiment, these channels might be approximately 10-30 straight lines inscribed every 1 mm in the affected area. In turn, each of these straight lines might be approximately 30-150 microns deep.

When used in conjunction with the interfacing surface of a proximity head, the straight lines might be inscribed in the direction of the flow of a meniscus to achieve hemi-wicking. (In other example embodiments, the lines might not be straight; they might take on any suitable orientation, pattern, or configuration.) Such hemi-wicking might allow the interfacing surface to be wetted using fewer perforations for the depositing and suctioning of an aqueous fluid. This in turn, reduces the complexity of the fluid-delivery network internal to the proximity head. Similarly, such hemi-wicking might allow for a lower rate of total liquid flow per area of the wetted surface and might improve the flow uniformity across the surface (e.g., the meniscus readily expands to fill the entire volume that the meniscus is designed to occupy on the interfacing surface). Additionally, because the liquid is more likely to flow on an interfacing surface with hemi-wicking rather than a flat hydrophobic surface, the hemi-wicking helps maintain and/or confine the meniscus. And since the interfacing surface is more readily wetted, the three-phase contact line of the meniscus moves freely on that surface, reducing the probability of trapping air bubbles beneath the meniscus, which in turn helps to obtain a fully developed meniscus. As discussed elsewhere, these same advantages might also be obtained with superhydrophobicity that promotes low friction flows.

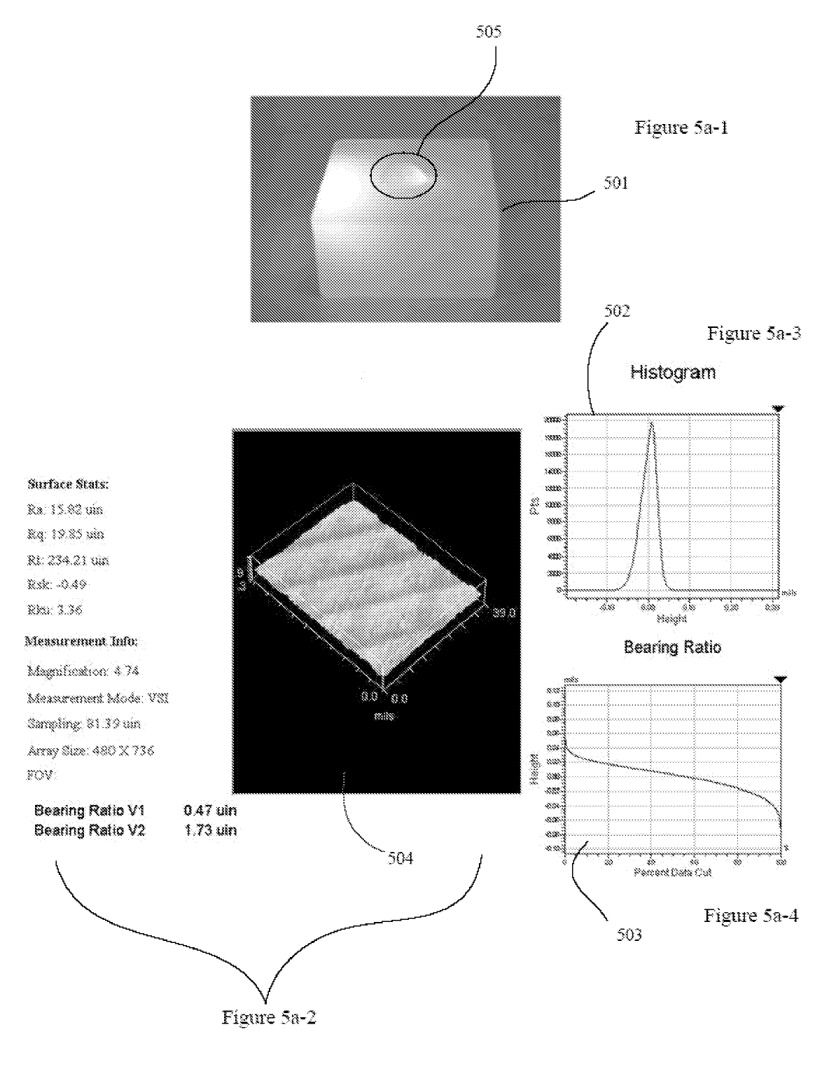

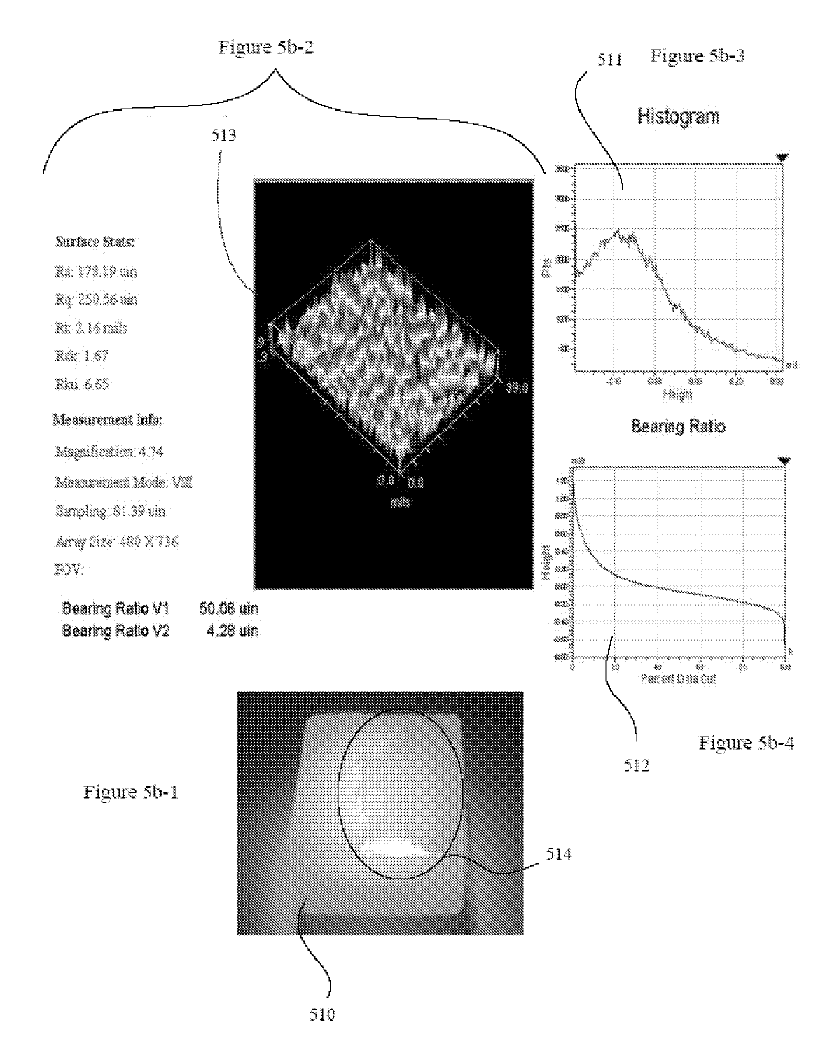

FIGS. 5a-1, 5a-2, 5a-3, and 5a-4 and FIGS. 5b-1, 5b-2, 5b-3, and 5b-4 are composite diagrams showing a comparison of the surface texture parameters for a thermoplastic solid with and without inscription of the solid's surface, in accordance with an example embodiment. FIG. 5a shows the case of a thermoplastic solid (e.g., KYNAR 740) without inscription of the solid's surface. The values of the surface texture parameters in this figure were measured by a vertical scanning interferometer, rather than the contact profilometer used to obtain the data shown in FIGS. 4a and 4b.

FIG. 5a-2 shows the values for five standard roughness parameters: (a) Ra is the average surface roughness or average deviation and has a value of approximately 15.82 microinch; (b) Rq is the root-mean-square roughness or first moment of the height distribution and has a value of approximately 19.85 microinch; (c) Rt is the maximum peak to valley height over the sample and has a value of approximately 234.21 microinch; (d) Rsk or skewness is the second moment of the height distribution and has a value of approximately minus 0.49; and (e) Rku or Kurtosis is the third moment of the height distribution and has a value of approximately 3.36 (on a scale from 0 to 8). FIG. 5a-1 shows a photograph of a water drop 501 resting on the surface of the solid, without wetting the surface by spreading over it. FIG. 5a-3 is a histogram 502 that shows little dispersion with respect to normalized height (in mils), e.g., the surface is relatively flat. This flatness is depicted in a three-dimensional surface 504.

FIG. 5a-4 shows a plot 503 of the bearing ratio expressed as a percentage (e.g., percent data cut) on the x-axis and a height in mils on the y-axis (ranging from approximately plus 0.041 mils to approximately minus 0.06 mils). It will be appreciated that that the bearing ratio is the ratio of the length of the bearing surface to the evaluation length at any specified depth. The bearing ratio simulates the effect of wear on the bearing surface.

Also shown in FIG. 5a are the parameters V1 and V2. The parameter V1 has a value of approximately 0.47 microinch. The parameter V1 is the volume of the material that will be removed during the run-in period and is part of the bearing ratio analysis. The parameter V2 has a value of approximately 1.73 microinch. The parameter V2 is the potential volume of retained lubricant and is also part of the bearing ratio analysis.

FIG. 5b shows the case of a thermoplastic solid (e.g., KYNAR 740) with inscription of the solid's surface to produce hemi-wicking, e.g., using the conical scribe described above. Here again, the values for the surface texture parameters in this figure were measured by a vertical scanning interferometer. FIG. 5b-2 shows the values for five standard roughness parameters: (a) Ra has a value of approximately 178.19 microinch; (b) Rq has a value of approximately 250.56 microinch; (c) Rt has a value of approximately 2.16 mils (e.g., 2160 microinch); (d) Rsk has a value of approximately 1.67; and (e) Rku has a value of approximately 6.65 (on a scale from 0 to 8).

When viewed in comparison with the corresponding parameter values shown in FIG. 5a-2, these parameter values indicate a surface texture with significantly more roughness. FIG. 5b-1 also shows a photograph of a water drop 514 spreading over the inscribed surface. FIG. 5b-3 is a histogram 511 that shows considerable dispersion with respect to normalized height (in mils), e.g., the surface is relatively jagged. This jaggedness is depicted in a three-dimensional surface 513. FIG. 5b-4 shows a plot 512 of the bearing ratio expressed as a percentage on the x-axis and a height in mils on the y-axis (ranging from approximately plus 1.2 mils to approximately minus 0.6 mils).

Also shown in FIG. 5b are the parameters V1 and V2. The parameter V1 has a value of approximately 50.06 microinch. The parameter V2 has a value of approximately 4.28 microinch.

It will be appreciated that (a) the inscription (micro-machining), melt printing, and roughening described above might be used to produce superhydrophobicity, as well as hemi-wicking, and that (b) superhydrophobicity might be used in place of hemi-wicking to confine, maintain, and/or facilitate (e.g., by promoting spreading or reducing friction) a flow of a meniscus, as described elsewhere. An example embodiment for producing superhydrophobicity might have pillars that are approximately 50 microns wide and troughs that are approximately 100 microns wide and approximately 148 microns deep, as described in the publication, David Quere, Surface Chemistry: Fakir Droplets, Nature Materials, Vol. 1 (September 2002): pp. 14-15.

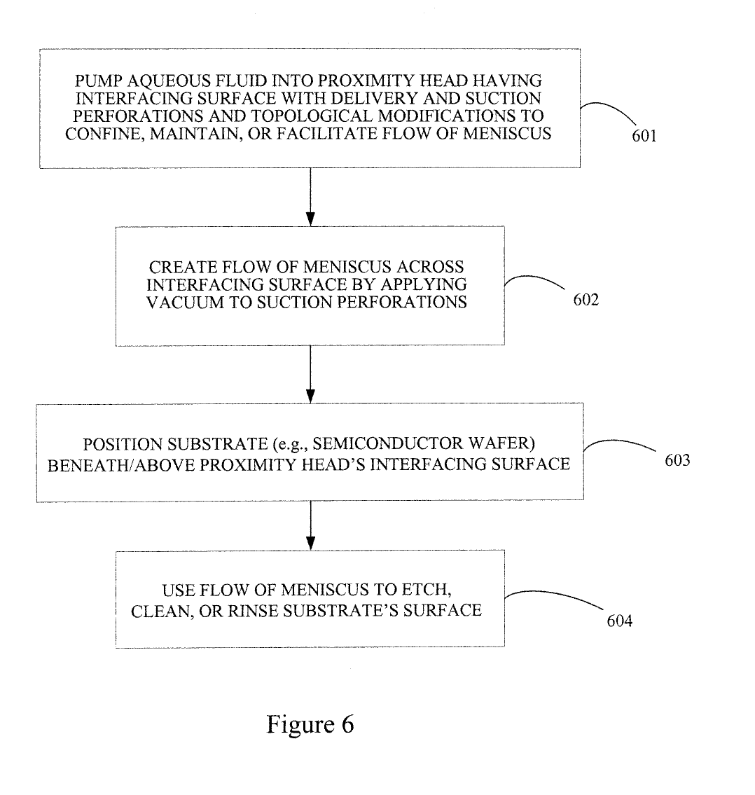

FIG. 6 is a flowchart diagram of a process for exposing a surface of a substrate (e.g., a semiconductor wafer) to a flow of a meniscus, in accordance with an example embodiment. In the process' first operation 601, a wet system (e.g., linear or rotational) pumps an aqueous liquid into a proximity head having an interfacing surface with delivery and suction perforations and topological modifications to confine, maintain, and/or facilitate a flow of a meniscus. In an example embodiment, these topographical modifications might include the inscribed/imprinted/roughened microchannels that support hemi-wicking, as described elsewhere. In an alternative example embodiment, these topographical modifications might include the inscribed/imprinted/roughened microchannels that produce superhydrophobicity conducive to low-friction flow, as also described elsewhere.

In the process' second operation 602, the wet system creates a flow of a meniscus across the interfacing surface by applying vacuum to the suction perforations. It will be appreciated that the process' first and second operations might occur at approximately the same time, in an example embodiment. In the process' third operation 603, the wet system positions a surface a substrate (e.g., a semiconductor wafer) beneath and/or above the interfacing surface of the proximity head. Then in the process's fourth operation 604, the wet system uses the flow of the meniscus to etch, clean, or rinse the surface of the substrate. Here again, it will be appreciated that the process' third and fourth operations might occur at approximately the same time, in an example embodiment.

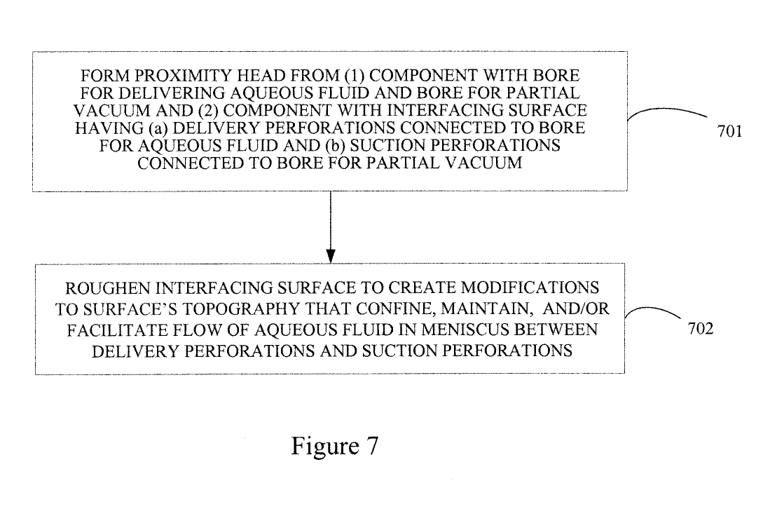

FIG. 7 is a flowchart diagram of a process for producing modifications to the topography of an interfacing surface of a proximity head, in accordance with an example embodiment. In the process' first operation 701, a proximity head is formed from: (1) a component with a bore for delivering an aqueous fluid and a bore for a partial vacuum; and (2) a component with an interfacing surface (e.g., that interfaces with a substrate through the medium of the aqueous fluid) having (a) delivery perforations connected to the bore for delivering the aqueous fluid and (b) suction perforations connected to the bore for the partial vacuum. In an example embodiment, the formation of the proximity head might be performed by an automated or partially-automated system that thermally bonds the two components together.

In the process' second operation 702, the interfacing surface is roughened to create modifications to the surface's topography that confine, maintain, and/or facilitate (e.g., by promoting spreading or reducing friction) a flow of a meniscus (e.g., of an aqueous fluid) between the delivery perforations and the suction perforations. Here again, the roughening of the interfacing surface might be performed by an automated or partially-automated system that inscribes or imprints microchannels which (a) support hemi-wicking or (b) produce superhydrophobicity. In an alternative example embodiment, the roughening might be achieved with an abrasive material such as Scotch-Brite™.

Although the foregoing example embodiments have been described in some detail for purposes of clarity of understanding, it will be apparent that certain changes and modifications may be practiced within the scope of the appended claims. For example, the fluid in the flow of the meniscus might be a non-aqueous fluid which exhibits behaviors similar to hydrophilicity or hydrophobicity, in alternative example embodiments. Or, in alternative example embodiments, the proximity head might be made of an inert (or relatively inert) material that is not thermoplastic, thermoset plastic, or ceramic. Accordingly, the example embodiments are to be considered as illustrative and not restrictive, and the inventions are not to be limited to the details given here, but may be modified within the scope and equivalents of the appended claims.

What is claimed is:

1. An apparatus, comprising:
a proximity head configured to cause a flow of an aqueous fluid in a meniscus across a surface of the proximity head, wherein the surface of the proximity head interfaces with a surface of a substrate through the flow and wherein the surface of the proximity head is composed of a material with modifications as to surface topography that alter the flow; and
a holder for the substrate that exposes the surface of the substrate to the flow.

2. An apparatus as in claim 1, wherein the alterations to the flow include one or more alterations selected from the group consisting of alterations that confine, maintain, and facilitate the flow.

3. An apparatus as in claim 1, wherein the modifications cause at least a part of the surface of the proximity head to become more hydrophilic.

4. An apparatus as in claim 3, wherein the modifications cause at least a part of the surface of the proximity head to exhibit hemi-wicking.

5. An apparatus as in claim 3, wherein the modifications include troughs cut into the surface of the proximity head through direct inscription.

6. An apparatus as in claim 5, wherein the modifications include troughs cut into the surface of the proximity head with a conical scribe having a tip selected from the group consisting of diamond and SiC.

7. An apparatus as in claim 1, wherein the modifications cause at least a part of the surface of the proximity head to become more hydrophobic.

8. An apparatus as in claim 7, wherein the modifications cause at least a part of the surface of the proximity head to produce superhydrophobicity.

9. An apparatus as in claim 7, wherein the modifications include a pattern created on the surface of the proximity head by a photo-machined template.

10. An apparatus as in claim 9, wherein a laser is used to photo-machine the template.

11. A method, comprising:
delivering a flow of an aqueous fluid in a meniscus across a surface of a proximity head, wherein the surface is composed of a material with modifications as to surface topography that alter the flow; and
exposing a surface of a substrate to the flow.

12. A method as in claim 11, wherein the alterations to the flow include one or more alterations selected from the group consisting of alterations that confine, maintain, and facilitate the flow.

13. A method as in claim 11, wherein the modifications as to surface topography cause at least a part of the surface of the proximity head to become more hydrophilic.

14. A method as in claim 13, wherein the modifications cause at least a part of the surface of the proximity head to exhibit hemi-wicking.

15. A method as in claim 14, wherein the modifications include troughs cut into the surface of the proximity head through direct inscription.

16. A method as in claim 15, wherein the modifications include troughs cut into the surface of the proximity head with a conical scribe having a tip selected from the group consisting of diamond and SiC.

17. A method as in claim 11, wherein the modifications cause at least a part of the surface of the proximity head to become more hydrophobic.

18. A method as in claim 17, wherein the modifications cause at least a part of the surface of the proximity head to produce superhydrophobicity.

19. A method as in claim 17, wherein the modifications include a pattern created on the surface of the proximity head by a photo-machined template.

20. A method, comprising:
forming a proximity head from a first component that includes at least one bore for delivering an aqueous fluid and at least one bore for a partial vacuum and a second component that includes a surface having delivery perforations connected to the at least one bore for delivering the aqueous fluid and suction perforations connected to the at least one bore for a partial vacuum; and
roughening the surface to create modifications as to surface topography that alter a flow of the aqueous fluid in a meniscus between the delivery perforations and the suction perforations.
